(19) United States
(12) Patent Application Publication
(10) Pub. No.: US 2013/0074772 A1
(43) Pub. Date: Mar. 28, 2013

(54) THIN-FILM SOLAR CELL MANUFACTURING SYSTEM

(71) Applicants: Shih-Wei Lee, Kaohsiung City (TW); Yao-Tsang Tsai, Tainan City (TW); Ming-Hung Lin, Pingtung County (TW)

(72) Inventors: Shih-Wei Lee, Kaohsiung City (TW); Yao-Tsang Tsai, Tainan City (TW); Ming-Hung Lin, Pingtung County (TW)

(73) Assignee: Axuntek Solar Energy, Pingtung County (TW)

(21) Appl. No.: 13/449,317

(22) Filed: Apr. 18, 2012

(30) Foreign Application Priority Data
Sep. 27, 2011 (TW) 100134778

(51) Int. Cl. C23C 16/458

(52) U.S. Cl. 118/724

(57) ABSTRACT

A manufacturing system for thin-film solar cell is disclosed in the present invention. The manufacturing system includes a chamber, a boat disposed inside the chamber, a solid substrate with a first precursor which has a first I B group and III A group, and a flexible substrate with a second precursor which has a second I B group and III A group, a gas controller for pouring reactant gas, and a heater for increasing the temperature of the chamber, so that the reactant gas reacts to the first precursor and the second precursor to form a chalcopyrite structure.

### BACKGROUND OF THE INVENTION

1. Field of the Invention

The present invention relates to a manufacturing system, and more particularly, to a manufacturing system capable of simultaneously manufacturing a solar cell with a solid substrate and a solar cell with a flexible substrate, and increasing productivity of the flexible substrate solar cell.

2. Description of the Prior Art

A solar cell with a solid substrate is generally manufactured by selenization technology. The solar cell with a flexible substrate is generally manufactured by roll-to-roll (R2R) technology and co-evaporation method. The R2R technology can not be applied to procedures of the solid substrate solar cell. The co-evaporation method utilizes a linear evaporation source in the R2R technology, the linear evaporation source can be made of copper material, the linear evaporation source is reacted in a high temperature condition, and volatilization volume of the linear evaporation source is hard to be controlled precisely, so that production of the conventional solar cell manufacturing method does not have preferable market competition. Therefore, design of a manufacturing system capable of simultaneously manufacturing a solid substrate solar cell and a flexible substrate solar cell, and increasing production of the flexible substrate solar cell is an important issue of the solar panel industry.

### SUMMARY OF THE INVENTION

The present invention provides manufacturing system capable of simultaneously manufacturing a solid substrate solar cell and a flexible substrate solar cell, and increasing productivity of the flexible substrate solar cell for solving above drawbacks.

According to the claimed invention, a manufacturing system for thin-film solar cell includes a chamber, a boat disposed inside the chamber, a solid substrate with a first precursor, a flexible substrate with a second precursor, a gas controller for pouring reactant gas into the chamber, and a heater for increasing temperature of the chamber, so that the reactant gas reacts to the first precursor and the second precursor to form a chalcopyrite structure. The first precursor includes a first IB group and III A group, and the second precursor includes a second IB group and III A group.

According to the claimed invention, the manufacturing system further includes a fixing component to fix the solid substrate and the flexible substrate. The fixing component includes a body and at least one engaging portion disposed on a lateral side of the body. The body is for holding the solid substrate and the flexible substrate, and the engaging portion is for blocking a surface of an assembly that comprises the solid substrate and the flexible substrate, so as to prevent the solid substrate from separating from the flexible substrate.

According to the claimed invention, the fixing component is a L-shaped blocking structure, the L-shaped blocking structure is disposed on the surface of the assembly, so that the solid substrate contacts against the flexible substrate tightly.

According to the claimed invention, the manufacturing system further includes a fixing component to fix the solid substrate and the flexible substrate. The fixing component includes a body and two engaging portions respectively disposed on two lateral sides of the body. The body is for holding the solid substrate and the flexible substrate, and the engaging portions are for clipping two surfaces of an assembly that comprises the solid substrate and the flexible substrate, so as to prevent the solid substrate from separating from the flexible substrate.

According to the claimed invention, the fixing component is a U-shaped clipping structure, the U-shaped clipping structure clips two opposite surfaces of the assembly, so that the solid substrate contacts against the flexible substrate tightly.

According to the claimed invention, a back of the solid substrate contacts a back of the flexible substrate for forming an assembly.

According to the claimed invention, a part of the flexible substrate is bent to hang on the solid substrate for forming an assembly, and the boat supports the assembly.

According to the claimed invention, the first IB group and the second IB group comprise copper, the first III A group and the second III A group comprise indium, gallium, or a combination thereof.

According to the claimed invention, the temperature of the chamber is increased to 400° C.˜550° C. by the heater.

According to the claimed invention, the flexible substrate is a metal foil.

According to the claimed invention, the reactant gas is hydrogen selenide or hydrogen sulphide.

According to the claimed invention, a manufacturing system for thin-film solar cell includes a chamber, a boat disposed inside the chamber, a supporter, at least two flexible metal substrates with a precursor, a gas controller for pouring reactant gas into the chamber, and a heater for increasing temperature of the chamber, so that the reactant gas reacts to the precursor to form a chalcopyrite structure. The precursor includes a IB group and III A group, and backs of the flexible metal substrates respectively contact two surfaces of the supporter for forming an assembly.

The manufacturing system of the present invention could simultaneously manufacture the solid substrate solar cell and the flexible substrate solar cell, and could increase the production of the flexible substrate solar cell effectively. According to variation of the arrangements, the solid substrate and the flexible substrate could be disposed inside the boat in the face-to-face manner or in the face-to-back manner for enhancing the production.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a manufacturing system for the thin-film solar cell according to an embodiment of the present invention.

FIG. 2 is a diagram of a fixing component according to a first embodiment of the present invention.

FIG. 3 is a diagram of a fixing component according to a second embodiment of the present invention.

FIG. 4 is a diagram of the fixing component according to a third embodiment of the present invention.

FIG. 5 is an assembly diagram of the assembly that comprises a solid substrate and a flexible substrate according to the other embodiment of the present invention.

FIG. 6 and FIG. 7 respectively are diagrams of the solid substrate and the flexible substrate according to different embodiments of the present invention.

### DETAILED DESCRIPTION

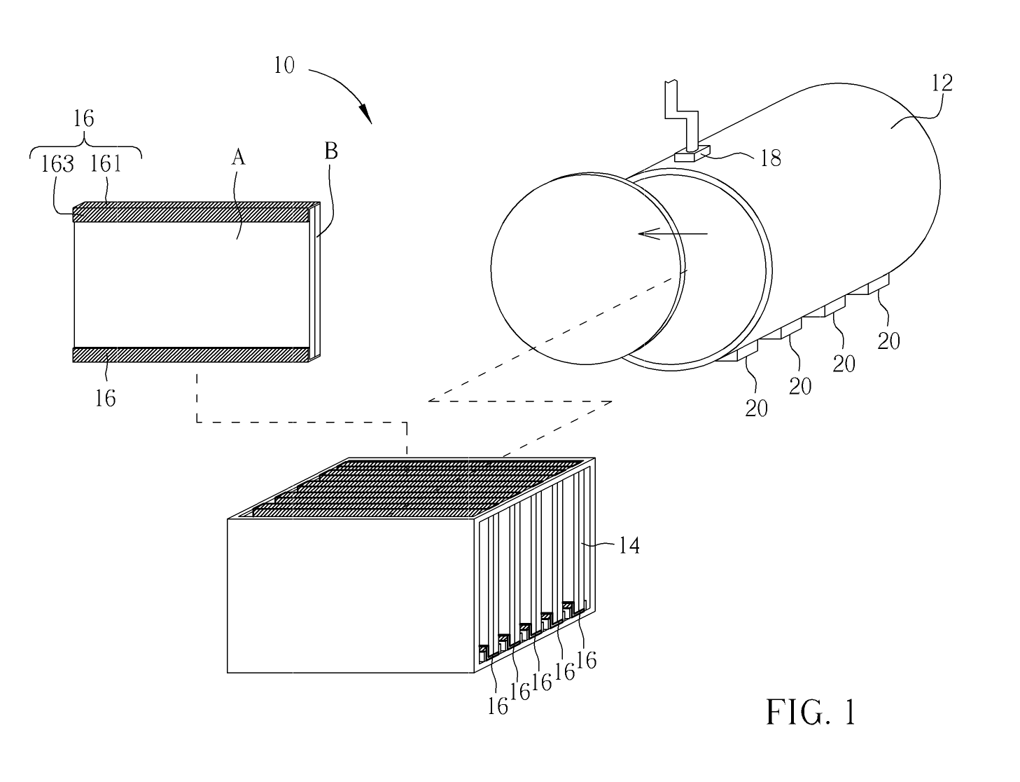

Please refer to FIG. 1. FIG. 1 is a functional block diagram of a manufacturing system 10 for the thin-film solar cell according to an embodiment of the present invention. It should be mentioned that a solid substrate A and a flexible substrate B introduced as following respectively has a precursor including IB group and III A group, such as Cu—Ga alloy layer/In layer, Cu—Ga—In alloy layer, or CuGaIn stacked layer. The precursors could be processed by selenization technology or sulfurization technology to form a chalcopyrite structure, such as copper indium diselenide, copper indium sulfur, copper indium gallium selenide, or copper indium gallium selenide sulfur. The precursors of the solid substrate A and the flexible substrate B could be made by the same or total different chemical composition, which depend on design demand. Further, the solid substrate A could be a soda lime glass (SLG) substrate or a non-alkali glass substrate. The flexible substrate B could be a metal foil or a sheet with high temperature resistance, such as greater than 400° C. A thickness of the flexible substrate B could be about 0.05˜0.5 mm.

As shown in FIG. 1, the manufacturing system 10 could include a chamber 12, a boat 14, the solid substrate A, the flexible substrate B, at least one fixing component 16, a gas controller 18 and a heater 20. The chamber 12 could be a hermetical container, so as to prevent the poisonous reactant gas from leaking out of the chamber 12. The boat 14 is movably disposed inside the chamber 12, and a plurality of grooves could be formed on the boat 14. The fixing component 16 could fix an assembly that comprises the solid substrate A and the flexible substrate B, and the assembly could be installed inside the boat 14 for accommodating inside the chamber 12 to react with reactant gas. The gas controller 18 could pour the reactant gas into the chamber 12, and the reactant gas could be hydrogen selenide or hydrogen sulphide. The heater 20 could increase temperature of the chamber 12 to 400° C.˜550° C., so that a chemical reaction between the reactant gas and the precursors of the solid substrate A and the flexible substrate B could be generated simultaneously. Then, the chalcopyrite structure could be formed after 20˜60 minutes.

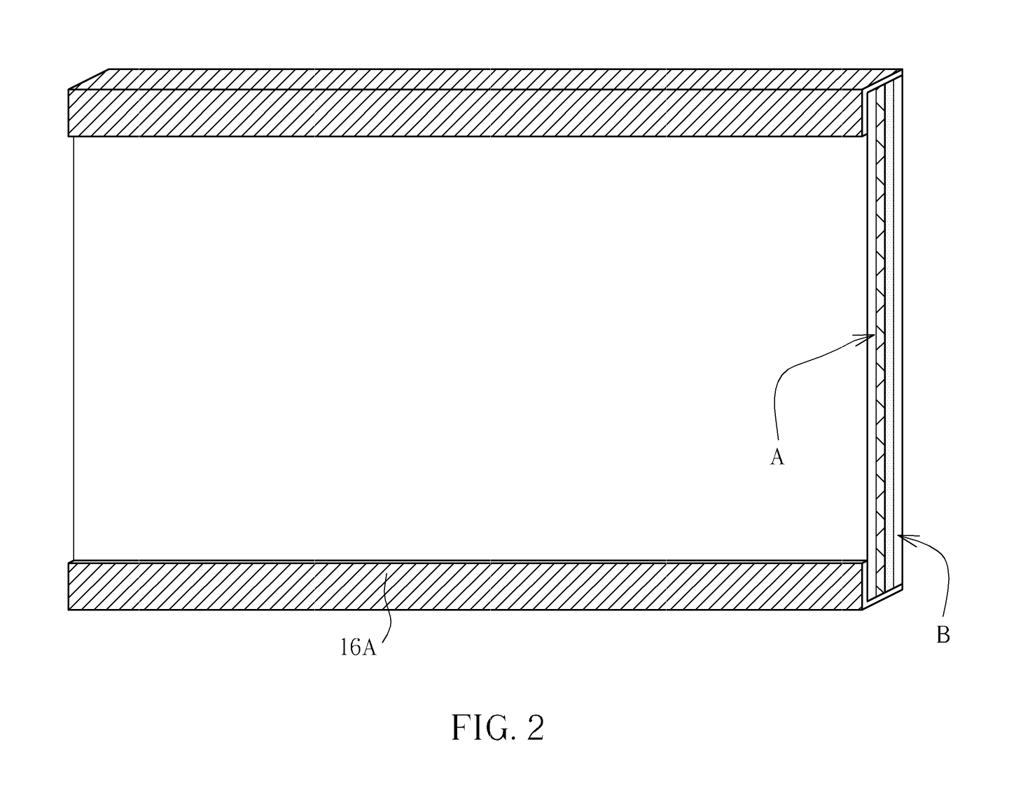

Please refer to FIG. 2. FIG. 2 is a diagram of the fixing component 16A according to a first embodiment of the present invention. The fixing component 16A includes a body 161, and an engaging portion 163 disposed on a lateral side of the body 161. The body 161 could be for holding the solid substrate A and the flexible substrate B. The engaging portion 163 could be for blocking a surface of the assembly that comprises the solid substrate A and the flexible substrate B, so as to prevent the solid substrate A from separating from the flexible substrate B. As shown in FIG. 2, the fixing component 16A could be a L-shaped structure. A back of the solid substrate A, such as the SLG substrate, could laterally contact a back of the flexible substrate B for forming the assembly. The L-shaped structure could be disposed on the surface of the assembly, and could keep the solid substrate A and the flexible substrate B completely matched with the grooves on the boat 14.

The flexible substrate B could be made of metal material. Due to preferable heat conductivity of the flexible substrate B (the metal foil), the solid substrate A and the flexible substrate B could be simultaneously and uniformly heated for high quality by tight contact of the backs of the solid substrate A and the flexible substrate B. In addition, the assembly that comprises the solid substrate A and the flexible substrate B could be accommodated inside the chamber 12 by the fixing components 16A of the first embodiment, so as to simultaneously execute the selenization procedure or the sulfurization procedure for increasing production.

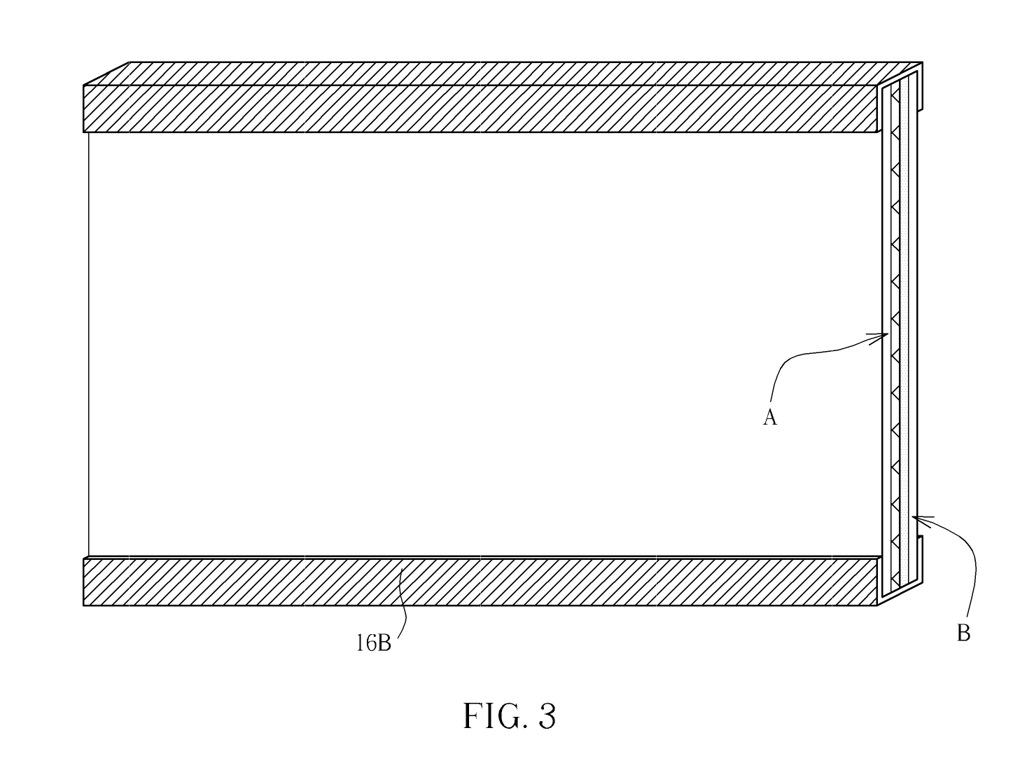

Please refer to FIG. 3. FIG. 3 is a diagram of the fixing component 16B according to a second embodiment of the present invention. The fixing component 16B includes the body 161 and two engaging portions 163. The engaging portions 163 are respectively disposed on two lateral sides of the body 161. The engaging portions 163 could clip two surfaces of the assembly that comprises the solid substrate A and the flexible substrate B, so as to prevent the solid substrate A from separating from the flexible substrate B. As shown in FIG. 3, the fixing component 16B could be a U-shaped structure. The assembly that comprises the solid substrate A and the flexible substrate B is the same as ones of the above-mentioned embodiment, and detail description is omitted herein for simplicity. The U-shaped structure (the fixing component 16B) could clip two opposite surfaces of the assembly, to keep the tight contact of the solid substrate A and the flexible substrate B. Thus, the assembly that comprises the solid substrate A and the flexible substrate B could be accommodated inside the chamber 12 by the fixing component 16B of the second embodiment, so as to simultaneously execute the selenization procedure or the sulfurization procedure for increasing the production.

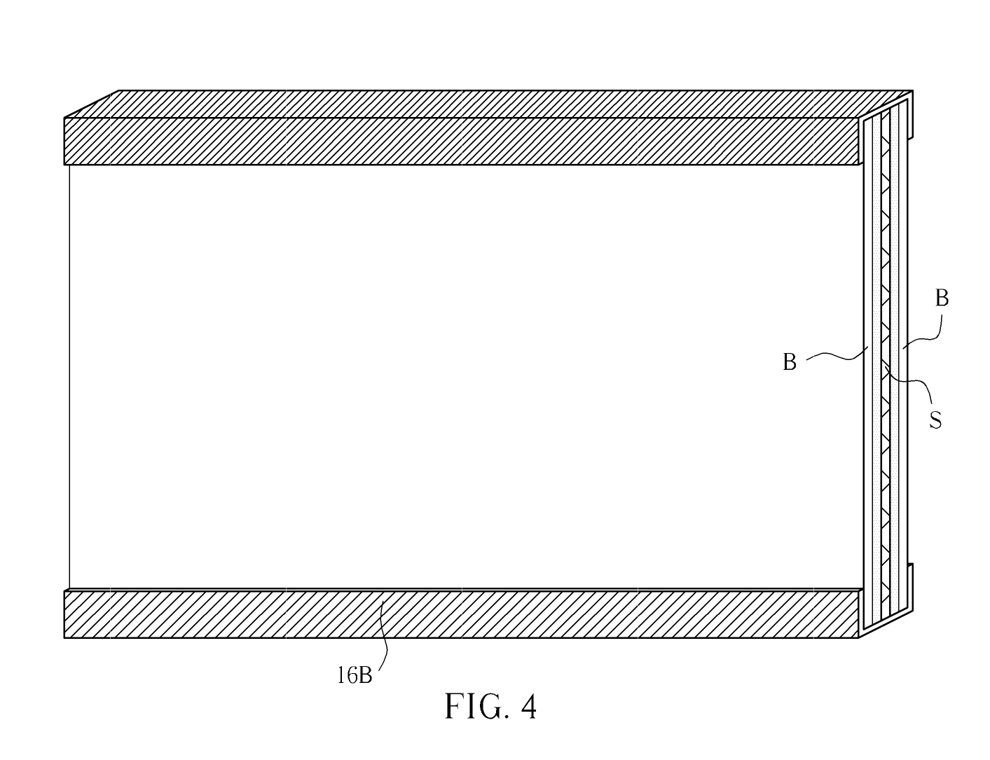

Please refer to FIG. 4. FIG. 4 is a diagram of the fixing component 16B according to a third embodiment of the present invention. Comparing to the first embodiment and the second embodiment, the plurality of flexible substrate B could be simultaneously processed by the selenization procedure or the sulfurization procedure in the third embodiment. First, backs of the flexible substrates B could respectively contact two surfaces of a supporter S, such as the SLG substrate or a component with high temperature resistance, for forming an assembly, so that the precursors of the flexible substrates B could respectively face outwardly. The back of the flexible substrate B could be made of metal foil. Due to the preferable heat conductivity of the metal foil, the supporter S and the flexible substrates B could be heated simultaneously and uniformly, so as to form the CIS-type layer with high quality by the selenization procedure or the sulfurization procedure. The fixing component 16B could be a clip structure including the body 161 and the engaging portions 163. In the third embodiment, the fixing component 16B could clip the opposite surfaces of the assembly, which comprises two flexible substrates B and the supporter S, to keep the tight contact of the flexible substrates B, and then the assembly that comprises two flexible substrates B could be accommodated inside the chamber 12 for executing the selenization procedure or the sulfurzation procedure.

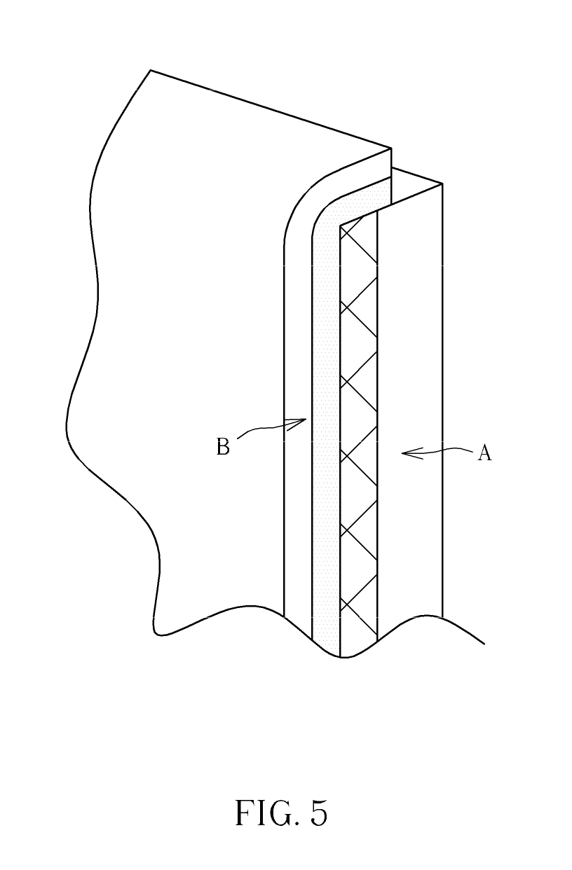

Besides, the flexible substrate B could be disposed on the solid substrate A due to the characteristic of flexibility, so as to form an assembly to be installed inside the boat 14. Please refer to FIG. 5. FIG. 5 is an assembly diagram of the assembly that comprises the solid substrate A and the flexible substrate B according to the other embodiment of the present invention. Because the flexible substrate B has a stretchable characteristic, a lateral part of the flexible substrate B could be bent to hang on the solid substrate A for forming the assembly shown in FIG. 5, and the assembly could be directly installed inside the boat 14, without utilizing the fixing component 16 to steady the solid substrate A and the flexible substrate B, for delivering into the chamber 12 to execute the selenization procedure or the sulfurization procedure.

In conclusion, the assembly of the above-mentioned embodiments could comprise the solid substrate A and the flexible substrate B, backs of the substrates contact to each other, for example, the solid substrate A contacts against the flexible substrate B so that the precursors of the solid substrate A and the flexible substrate B could face outwardly and respectively. Therefore, the reactant gas controlled by the gas controller 18 could be reacted with the precursor to form the chalcopyrite structure.

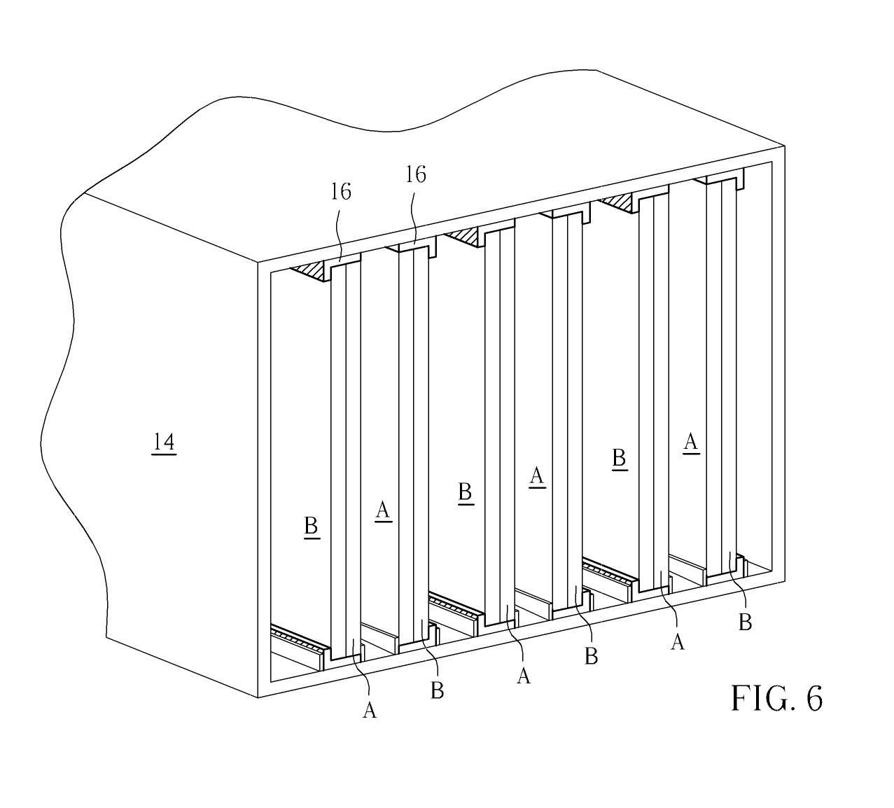

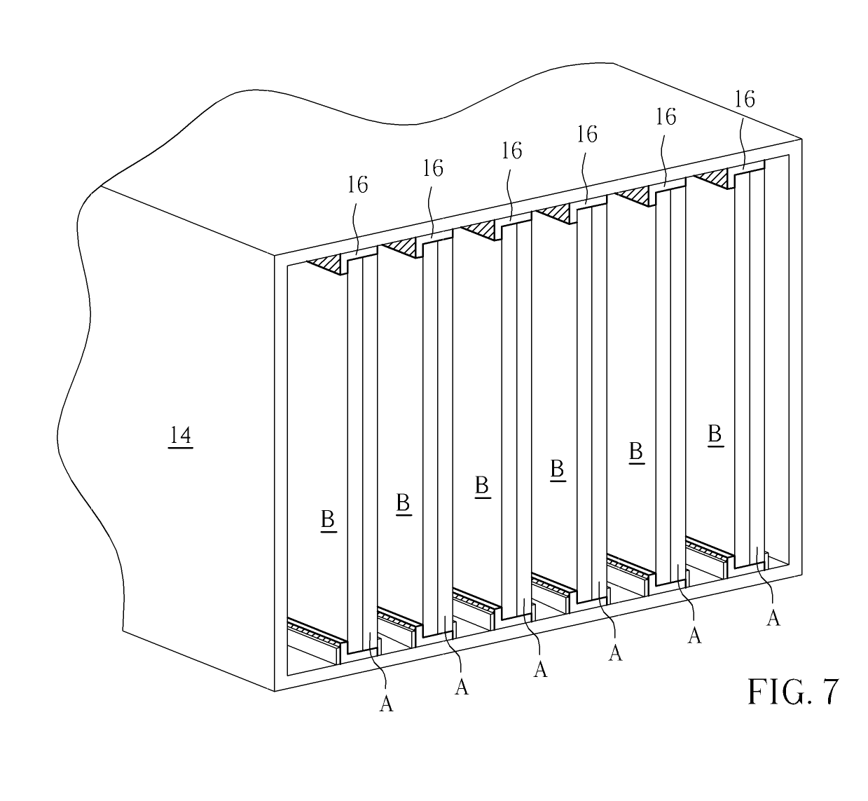

Please refer to FIG. 6 and FIG. 7. FIG. 6 and FIG. 7 respectively are diagrams of the solid substrate A and the flexible substrate B according to different embodiments of the present invention. As shown in FIG. 6, the precursors of the solid substrates A could be disposed in a face-to-face manner, and the precursors of the flexible substrates B could also be disposed in the face-to-face manner. In addition, the solid substrate A could tightly contact against the flexible substrate B via the L-shaped structure and the grooves on the boat 14. As shown in FIG. 7, the precursor of the solid substrate A could be disposed adjacent to the precursor of the flexible substrate B in the face-to-face manner. The present invention could further put the flexible substrate B on the back (a non-reacted side) of the solid substrate A, and the thickness of the flexible substrate B has no interference to the reacting space that the precursor of the solid substrate A demands, so that the manufacturing system 10 of the present invention could have greater production than the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing system for thin-film solar cell, the manufacturing system comprising:
a chamber;
a boat disposed inside the chamber;
a solid substrate with a first precursor, the first precursor comprising a first IB group and III A group;
a flexible substrate with a second precursor, the second precursor comprising a second IB group and III A group;
a gas controller for pouring reactant gas into the chamber; and
a heater for increasing temperature of the chamber, so that the reactant gas reacts to the first precursor and the second precursor to form a chalcopyrite structure.

2. The manufacturing system of claim 1, wherein the manufacturing system further comprises a fixing component to fix the solid substrate and the flexible substrate, the fixing component comprises a body and at least one engaging portion disposed on a lateral side of the body, the body is for holding the solid substrate and the flexible substrate, and the engaging portion is for blocking a surface of an assembly that comprises the solid substrate and the flexible substrate, so as to prevent the solid substrate from separating from the flexible substrate.

3. The manufacturing system of claim 2, wherein the fixing component is a L-shaped blocking structure, the L-shaped blocking structure is disposed on the surface of the assembly, so that the solid substrate contacts against the flexible substrate tightly.

4. The manufacturing system of claim 1, wherein the manufacturing system further comprises a fixing component to fix the solid substrate and the flexible substrate, the fixing component comprises a body and two engaging portions respectively disposed on two lateral sides of the body, the body is for holding the solid substrate and the flexible substrate, and the engaging portions are for clipping two surfaces of an assembly that comprises the solid substrate and the flexible substrate, so as to prevent the solid substrate from separating from the flexible substrate.

5. The manufacturing system of claim 4, wherein the fixing component is a U-shaped clipping structure, the U-shaped clipping structure clips two opposite surfaces of the assembly, so that the solid substrate contacts against the flexible substrate tightly.

6. The manufacturing system of claim 1, wherein a back of the solid substrate contacts a back of the flexible substrate for forming an assembly.

7. The manufacturing system of claim 1, wherein a part of the flexible substrate is bent to hang on the solid substrate for forming an assembly, and the boat supports the assembly.

8. The manufacturing system of claim 1, wherein the first IB group and the second IB group comprise copper, the first III A group and the second III A group comprise indium, gallium, or a combination thereof.

9. The manufacturing system of claim 1, wherein the temperature of the chamber is increased to 400° C.˜550° C. by the heater.

10. The manufacturing system of claim 1, wherein the flexible substrate is a metal foil.

11. The manufacturing system of claim 1, wherein the reactant gas is hydrogen selenide or hydrogen sulphide.

12. A manufacturing system for thin-film solar cell, the manufacturing system comprising:
a chamber;
a boat disposed inside the chamber;
a supporter;
at least two flexible metal substrates with a precursor, the precursor comprising a IB group and III A group, and backs of the flexible metal substrates respectively contacting two surfaces of the supporter for forming an assembly;
a gas controller for pouring reactant gas into the chamber; and
a heater for increasing temperature of the chamber, so that the reactant gas reacts to the precursor to form a chalcopyrite structure.

13. The manufacturing system of claim 12, wherein the manufacturing system further comprises a fixing component to fix the flexible metal substrates, the fixing component comprises a body and two engaging portions respectively disposed on two lateral sides of the body, the body is for holding the flexible metal substrates and the supporter, and the engaging portions are for clipping two surfaces of an assembly that comprises the flexible metal substrate and the supporter, so as to prevent the flexible metal substrates from separation.

14. The manufacturing system of claim 13, wherein the fixing component is a U-shaped clipping structure, the U-shaped clipping structure clips two opposite surfaces of the assembly, so that the flexible metal substrate contacts against the supporter tightly.

15. The manufacturing system of claim 12, wherein a part of the flexible metal substrate is bent to hang on the supporter for forming an assembly, and the boat supports the assembly.

16. The manufacturing system of claim 12, wherein the temperature of the chamber is increased to 400° C.˜550° C. by the heater.

17. The manufacturing system of claim 12, wherein the IB group comprises copper, the III A group comprises indium, gallium, or a combination thereof.

18. The manufacturing system of claim 12, wherein the reactant gas is hydrogen selenide and hydrogen sulphide.
